(19) United States
(12) Patent Application Publication
(10) Pub. No.: US 2006/0145197 A1
(43) Pub. Date: Jul. 6, 2006

(54) CMOS image sensor and method for fabricating the same

(76) Inventor: Seoung Won Baek, Incheon-city (KR)

Correspondence Address: Song K. Jung;MCKENNA LONG & ALDRIDGE LLP, 1900 K Street, N.W., Washington, DC, 20006, US

(21) Appl. No.: 11/319,262

(22) Filed: Dec. 29, 2005

(30) Foreign Application Priority Data
Dec. 30, 2004 (KR) 10-2004-0116547

(51) Int. Cl. H01L 29/768

(52) U.S. Cl. 257/222

(57) ABSTRACT

A CMOS image sensor and a method for fabricating the same provides a microlens pattern profile with a rectangular shape to facilitate a reflow process of a microlens and improve its curvature, thereby improving concentration efficiency of light and improving characteristics of the image sensor. The CMOS image sensor includes a plurality of photodiodes arranged on a semiconductor substrate; a plurality of color filters disposed in correspondence to the photodiodes; a planarization layer formed on the entire surface of the semiconductor substrate including the color filters; first microlenses having a rectangular shape formed on the planarization layer to correspond to the photodiodes; and second microlenses formed to surround the first microlenses.

### CROSS REFERENCE TO RELATED APPLICATIONS

This application claims the benefit of Korean Patent Application No. 10-2004-0116547, filed on Dec. 30, 2004, which is hereby incorporated by reference for all purposes as if fully set forth herein.

### BACKGROUND OF THE INVENTION

1. Field of the Invention

The present invention relates to an image sensor, and more particularly, to a complementary metal-oxide-semiconductor (CMOS) image sensor and a method for fabricating the same in which concentration efficiency of light is maximized to improve characteristics of the image sensor.

2. Discussion of the Related Art

Image sensors are semiconductor devices that convert an optical image to an electrical signal. They include CMOS image sensors having a number of metal-oxide-semiconductor (MOS) transistors, corresponding to the number of pixels, integrated on a single chip with peripheral circuitry for sequentially outputting the electrical signals of the MOS transistors. CMOS image sensors use complimentary MOS technology to achieve decreased feature size, power consumption, and fabrication costs and are applicable to such products as digital cameras, cellular telephones, personal digital assistants, notebook computers, bar-code readers, and toys. A CMOS image sensor is largely comprised of a signal processing chip which includes an array of photodiodes provided with an amplifier, an analog-to-digital converter, an internal voltage regulator, a timing generator, and digital logic circuitry.

To enhance the photosensitivity of a CMOS image sensor, its fill factor may be improved; that is, the photodiode area is increased with respect to the area of the device itself. Increase of the fill factor is limited, however, by the presence of the associated logic and signal processing circuitry of each photodiode. Enhanced photosensitivity may also be achieved by focusing incident light, which is deflected by, for example, a microlens provided for each photodiode to concentrate the incident light into the photodiode and away from the adjacent areas where there is no photodiode surface. In doing so, light parallel to a light axis of the microlens is refracted by the microlens so that a focal point is formed at a point along the light axis.

Referring to FIG. 1, a typical CMOS image sensor includes at least one photodiode 11 formed in a semiconductor substrate (not shown) to generate charges in response to incident light, an interlayer dielectric layer 12 formed on an entire surface of the semiconductor substrate including the photodiodes 11, a passivation layer 13 formed on the interlayer dielectric layer 12, an RGB color filter layer 14 formed on the passivation layer 13 to pass light according to its wavelength, a planarization layer 15 formed on the color filter layer 14, and a convex microlens 16 having a certain curvature formed on the planarization layer 15 to focus the filtered light onto the photodiodes 11.

The curvature and height of the microlens 16 are determined considering various factors such as a focal point of focused light. A resin such as polymer is generally used as the microlens 16. The microlens 16 is formed by deposition, patterning, and reflow processes. An optimized size and thickness and the curvature radius of the microlens 16 should be determined according to the size, relative position, and shape of a unit pixel, the height, relative position, and size of an aperture formed in the light-shielding layer, and photodiode thickness. A photoresist is generally used as the microlens 16. The photoresist is patterned by exposing and developing processes to form a photoresist pattern, which may be subject to a reflow process.

The pattern profile of the microlens depends on the focusing characteristics of the photoresist, such that the microlens profile is varied, and its fabrication process parameters depend on structural conditions of a lower layer. The microlens 16 is formed to improve light concentration efficiency and is a major factor in determining image sensor characteristics. Upon receiving a light signal, the microlens 16 concentrates more light onto the photodiodes 11, to be passed through (filtered by) the respective color filters of the color filter layer 14. The filtered light strikes the corresponding photodiodes 11.

Because the condition of the photoresist pattern is unstable when the related art CMOS image sensor is fabricated, concentration efficiency of the light is deteriorated. This could deteriorate performance of the CMOS image sensor.

### SUMMARY OF THE INVENTION

Accordingly, the present invention is directed to a CMOS image sensor and a method for fabricating the same that substantially obviates one or more problems due to limitations and disadvantages of the related art.

An advantage of the present invention is to provide a CMOS image sensor and a method for fabricating the same in which a microlens pattern profile is formed with a rectangular shape to facilitate a reflow process of a microlens and improve its curvature, thereby improving concentration efficiency of light and improving the characteristics of the image sensor.

Additional advantages and features of the invention will be set forth in part in the description which follows, and in part will become apparent from the description, or may be learned by practice of the invention. These and other advantages of the invention may be realized and attained by the structure particularly pointed out in the written description and claims hereof as well as the appended drawings.

To achieve these and other advantages in accordance with the purpose of the invention, as embodied and broadly described herein, a CMOS image sensor comprises a plurality of photodiodes arranged on a semiconductor substrate; a plurality of color filters disposed in correspondence to the photodiodes; a planarization layer formed on the entire surface of the semiconductor substrate including the color filters; first microlenses having a rectangular shape formed on the planarization layer to correspond to the photodiodes; and second microlenses formed to surround the first microlenses.

According to another aspect of the present invention, a method for fabricating a CMOS image sensor comprises forming a plurality of color filters in correspondence to a plurality of photodiodes arranged on a semiconductor substrate; forming a planarization layer on an entire surface of the semiconductor substrate including the color filters; forming first microlenses having a rectangular shape on the planarization layer to correspond to the photodiodes; and forming second microlenses corresponding to the respective photodiodes and surrounding the first microlenses.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiment(s) of the invention and together with the description serve to explain the principles of the invention.

In the drawings:

FIG. 1 is a structural sectional view a typical CMOS image sensor; and

FIGS. 2A-2D are cross-sectional views respectively illustrating a method for fabricating a CMOS image sensor according to an exemplary embodiment of the present invention.

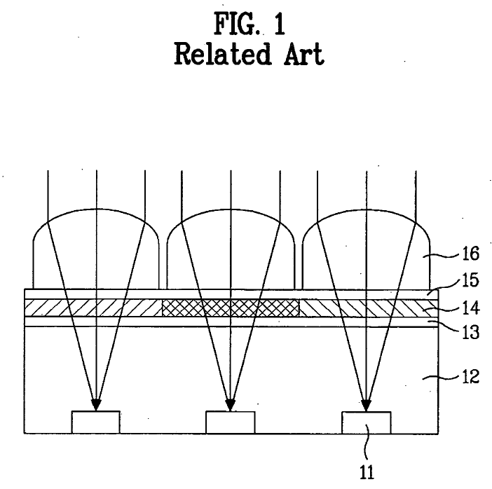

### DETAILED DESCRIPTION OF THE INVENTION

Reference will now be made in detail to exemplary embodiments of the present invention, examples of which are illustrated in the accompanying drawings. Wherever possible, like reference designations will be used throughout the drawings to refer to the same or similar parts.

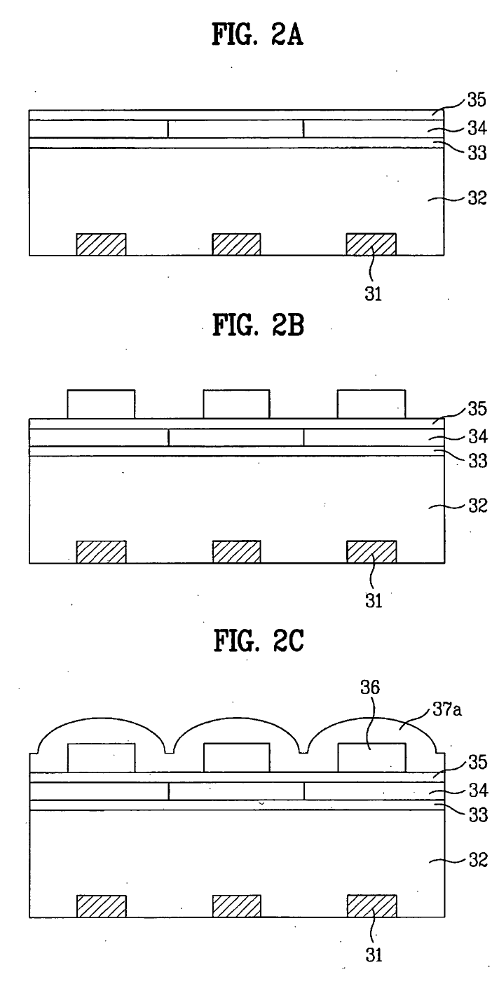

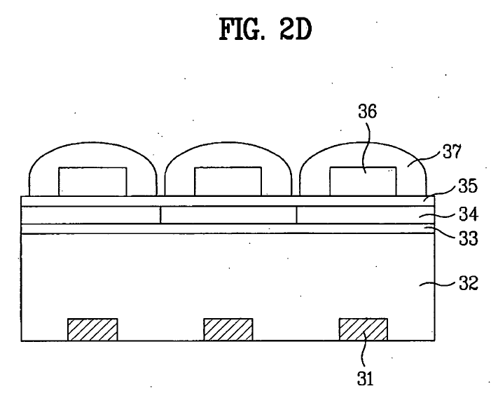

FIGS. 2A-2D respectively illustrate sequential process steps of a method for fabricating the CMOS image sensor according to an embodiment of the present invention.

Referring to FIG. 2A, an interlayer dielectric layer 32 is formed on the entire surface of the semiconductor substrate (not shown) in which a plurality of photodiodes 31 for generating charges in response to incident light are formed. A photogate-type device may be used as the light-sensing device. The interlayer dielectric layer 32 may be formed of one or several layers. For example, a light-shielding layer (not shown) may be formed on one interlayer dielectric layer to prevent light from entering a portion other than the photodiodes 31, and another interlayer dielectric layer may be formed on the light-shielding layer. Subsequently, a passivation layer 33 is formed on the interlayer dielectric layer 32 to protect a device from moisture and abrasion. The passivation layer 33 is coated with a salt resist, which is patterned to form a color filter layer 34 of constant intervals for filtering the incident light according to wavelength, i.e., color. A planarization layer 35 is formed on the color filter layer 34 to obtain a flat surface for setting a focal distance and for receiving a lens layer.

Referring to FIG. 2B, the planarization layer 35 is coated with a material layer for forming the first microlenses. The material layer is formed of a photoresist or an oxide such as silicon oxynitride. Subsequently, the material layer for first microlens formation is selectively patterned by exposing and developing processes, thereby forming a plurality of first microlenses 36 on the planarization layer 35, each first microlens being formed in correspondence to the disposition of a corresponding photodiode 31.

Referring to FIG. 2C, the entire surface of the semiconductor substrate, including the first microlenses 36, is coated with a material layer 37a for forming the second microlenses. In doing so, the material layer 37a for second microlens formation is imparted with a curvature according to the rectangular shape of the first microlenses 36.

Referring to FIG. 2D, the material layer 37a for the second microlenses is selectively patterned by exposing and developing processes, thereby forming the second microlenses 37 surrounding the respective first microlenses 36. Thus, each of the first and second microlenses 36 and 37 may be formed at constant intervals in correspondence to one of the photodiodes 31. The second microlenses 37 may be hardened by a reflow process or by ultraviolet light irradiation to maintain an optimized curvature radius. The reflow process may be performed using a hot plate or a furnace. The resulting curvature of the microlenses, as well as their light focusing efficiency, depends on a heating and contracting operation. Therefore, it is important to form the microlenses with a shape that can obtain the optimized curvature for maximizing the amount of light to be transmitted to the photodiodes 31. The optimized curvature depends on the size (width) and (vertical) height of the microlenses and thus relates to the degree of integration of the CMOS image sensor. A more highly integrated device would necessitate a smaller and shorter microlens. Therefore, in the CMOS image sensor according to an embodiment of the present invention, light enters the photodiodes 31 while transmitting the second microlenses 37 and the first microlenses 36 so as to improve its light concentration (focusing) efficiency and the resolution of the color filter layer 34.

In the process of forming the microlenses according to an embodiment of the present invention, the coating of a material such as silicon oxynitride, having a refractive index greater than that of a photoresist for forming the hemispheric microlenses, is applied after formation of the color filter layer and the planarization layer. Thus, the rectangular microlenses are formed before the hemispheric microlenses are formed. The first and second microlenses 36 and 37 may be formed using a photoresist or an oxide having the same or dissimilar refractive indexes.

Accordingly, a CMOS image sensor according to an embodiment the present invention is shown in FIG. 2D. The CMOS image sensor includes at least one photodiode 31 formed in a semiconductor substrate (not shown) to generate charges in response to incident light; an interlayer dielectric layer 32 formed on an entire surface of the semiconductor substrate including the photodiodes; a passivation layer 33 formed on the interlayer dielectric layer; a color filter layer 34 formed on the passivation layer, the color filter layer comprising a plurality of color filters corresponding to the photodiodes, to transmit light filtered according to wavelength; a planarization layer 35 formed on the entire surface of the semiconductor substrate including the color filter layer; first microlenses 36, each having a rectangular shape, formed on the planarization layer to correspond to the photodiodes; and second microlenses 37, each having a convex hemispheric shape, formed to correspond to the photodiodes and to surround the respective first microlenses.

The second microlenses 37 may be formed of photoresist, and the first microlenses 36 may be formed of either a photoresist or an oxide such as silicon oxynitride (SiON). The photoresist constituting the first microlenses 36 may have a refractive index greater than that of the photoresist constituting the second microlenses 37. The first microlenses 36 may be formed of a material having a refractive index different from or the same as that of the second microlenses 37.

As described above, according to the CMOS image sensor and the method for fabricating the same, since the microlenses are formed at a secondary coating level, the profile of the microlenses is stably formed to improve focusing efficiency of the light. By improving the focusing efficiency, more light passes through the color filter layers to strike the photodiodes, such that improved resolution is obtained in the color filter layer, thereby improving image sensor performance. In addition, since the microlenses have a multilevel structure, the processes prior to the process of forming the microlenses are not required during the rework process, simplifying the rework process and reducing costs accordingly.

It will be apparent to those skilled in the art that various modifications and variations can be made in the present invention without departing from the spirit or scope of the invention. Thus, it is intended that the present invention covers such modifications and variations provided they come within the scope of the appended claims and their equivalents.

What is claimed is:

1. A CMOS image sensor, comprising:
a plurality of photodiodes arranged on a semiconductor substrate;
a plurality of color filters disposed in correspondence to the photodiodes;
a planarization layer formed on the entire surface of the semiconductor substrate including the color filters;
first microlenses having a rectangular shape formed on the planarization layer to correspond to the photodiodes; and
second microlenses formed to surround the first microlenses.

2. The CMOS image sensor according to claim 1, wherein the second microlenses have a convex hemispherical shape.

3. The CMOS image sensor according to claim 1, wherein the first and second microlenses are formed of materials having different refractive indexes.

4. The CMOS image sensor according to claim 1, wherein the first and second microlenses are formed of materials having the same refractive indexes.

5. The CMOS image sensor according to claim 4, wherein the material of each of the first and second microlenses is one of a photoresist and an oxide.

6. The CMOS image sensor according to claim 1, further comprising:
an interlayer dielectric layer formed on an entire surface of the semiconductor substrate including the photodiodes; and
a passivation layer formed on the interlayer dielectric layer, wherein the color filters are formed on the passivation layer at constant intervals.

7. A method for fabricating a CMOS image sensor, comprising:
forming a plurality of color filters in correspondence to a plurality of photodiodes arranged on a semiconductor substrate;
forming a planarization layer on an entire surface of the semiconductor substrate including the color filters;
forming first microlenses having a rectangular shape on the planarization layer to correspond to the photodiodes; and
forming second microlenses corresponding to the respective photodiodes and surrounding the first microlenses.

8. The method according to claim 7, wherein the first and second microlenses are formed of materials having different refractive indexes.

9. The method according to claim 8, wherein the material of each of the first and second microlenses is one of a photoresist and an oxide.

10. The method according to claim 7, said second microlens forming comprising:
coating the entire surface of the semiconductor substrate including the first microlenses with a material layer for microlens formation;
selectively patterning the material layer;
reflowing the patterned material layer to form the second microlenses having a convex hemispheric shape; and
hardening the second microlenses by irradiating an entire surface of the second microlenses with ultraviolet light.

11. The method according to claim 7, further comprising:
forming an interlayer dielectric layer on the semiconductor substrate in which the photodiodes are formed; and
forming a passivation layer on the interlayer dielectric layer,
wherein the color filters are formed on the passivation layer at constant intervals.

12. A method of forming microlenses for an image device comprising:
forming first microlenses having a rectangular shape on a planarization layer wherein each microlens corresponds to a photodiode in the image device; and
forming second microlenses corresponding to and surrounding the first microlenses.

13. The method according to claim 12, wherein the first and second microlenses are formed of materials having different refractive indexes.

14. The method according to claim 13, wherein the material of each of the first and second microlenses is one of a photoresist and an oxide.

15. The method according to claim 12, wherein forming said second microlens comprises:
coating the entire surface of the image device including the first microlenses with a material layer for microlens formation;
selectively patterning the material layer;
reflowing the patterned material layer to form the second microlenses having a convex hemispheric shape; and
hardening the second microlenses by irradiating an entire surface of the second microlenses with ultraviolet light.
